(19) United States
(12) Patent Application Publication
(10) Pub. No.: US 2011/0232942 A1
(43) Pub. Date: Sep. 29, 2011

(54) MULTI-LAYER WIRING BOARD AND METHOD OF MANUFACTURING MULTI-LAYER WIRING BOARD

(75) Inventor: Hiroyuki UEMATSU, Tokyo (JP)

(73) Assignee: TDK CORPORATION, TOKYO (JP)

(21) Appl. No.: 13/069,741

(22) Filed: Mar. 23, 2011

(30) Foreign Application Priority Data
Mar. 26, 2010 (JP) 2010-072931

(51) Int. Cl. H05K 1/00; H05K 3/00

(52) U.S. Cl. 174/250; 29/829

(57) ABSTRACT

A multi-layer wiring board includes a substrate; a land including a first conductive member arranged on the substrate; a second conductive member that is deposited on a surface of the first conductive member, which is a surface distant from the substrate; and a stress relaxation layer arranged between the first conductive member and the second conductive member; and a connection portion that makes contact with the land and that is electrically connected to the land.

### CROSS-REFERENCE TO RELATED APPLICATIONS

This application is based upon and claims the benefit of priority from Japanese Patent Application No. 2010-072931, filed on Mar. 26, 2010, the entire contents of which are incorporated herein by reference.

### BACKGROUND OF THE INVENTION

1. Field of the Invention

The present invention relates to a multi-layer wiring board including interlayer circuits and a method of manufacturing a multi-layer wiring board.

2. Description of the Related Art

Many recent circuit boards are highly dense. As a board on which a circuit can be mounted in a high density, multi-layer wiring boards in which interconnect traces of multiple layers are formed in a plate-like member have been proposed.

For example, Japanese Laid-open Patent Publication No. 2009-239184 describes a multi-layer printed wiring board (multi-layer wiring circuit board) including interlayer circuits and in which a via receiving land of a via interconnected with an upper layer and an interconnect circuit are provided on at least one of the inner layer circuits. It is also described in Japanese Laid-open Patent Publication No. 2009-239184 that, when the thickness of the via receiving land is Tv, the thickness of the interconnect circuit is Tl, the thickness of an interlayer insulating resin deposited on the inner circuit is Tr, and Tr>Tv>Tl is satisfied, both via filling performance or adherence to the inside of a via hole and interlayer insulation reliability can be achieved with finer interconnects and a reduced via diameter.

As described in Japanese Laid-open Patent Publication 2009-239184, by locating the interconnect connected to a via at a position higher than other interconnects, the diameter of the via can be small and thus the via and the interconnect can be connected securely. In this case, however, a stress larger than those applied to other interconnects and caused due to thermal change during manufacturing or during the use of the board is applied to the interconnect connected to the via. When such a large load is applied, the interconnect deforms and thus problems may be caused in the interconnects.

### SUMMARY OF THE INVENTION

A multi-layer wiring board according to an aspect of the present invention includes a substrate; a land that includes a first conductive member arranged on the substrate, a second conductive member deposited on a surface of the first conductive member, and a stress relaxation layer arranged between the first conductive member and the second conductive member, the surface of the first conductive member being distant from the substrate; and a connection portion that makes contact with the land and that is electrically connected to the land.

A method of manufacturing a multi-layer wiring board according to another aspect of the present invention includes adhering a resin layer to a plate-like substrate with a first metal layer arranged on one surface and a second metal layer arranged on the other surface on the surface on which the first metal layer is arranged; forming a hole that penetrates through the first metal layer and the substrate and extends to the second metal layer; patterning the resin layer, leaving at least the resin layer around the hole; and filling the hole, the first metal layer, and the resin layer with metal.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a cross-sectional view of a schematic configuration of an embodiment of a multi-layer wiring board;

FIG. 2 is a cross-sectional view of the multi-layer wiring board in FIG. 1 taken along the line II-II;

FIG. 3 is a cross-sectional view of the multi-layer wiring board in FIG. 1 taken along the line III-III;

FIG. 4 is a cross-sectional view of a schematic configuration of another embodiment of the multi-layer wiring board;

FIG. 5 is a cross-sectional view of a schematic configuration of another embodiment of the multi-layer wiring board;

FIG. 6A is a schematic diagram of vias connected to a land, illustrating an example of the relationship thereof;

FIG. 6B is a schematic diagram of vias connected to a land, illustrating an example of the relationship thereof;

FIG. 6C is a schematic diagram of vias connected to a land, illustrating an example of the relationship thereof;

FIG. 7A is an illustrative diagram illustrating an example of a method of manufacturing a multi-layer wiring board;

FIG. 7B is an illustrative diagram illustrating the example of the method of manufacturing a multi-layer wiring board;

FIG. 7C is an illustrative diagram illustrating the example of the method of manufacturing a multi-layer wiring board;

FIG. 7D is an illustrative diagram illustrating the example of the method of manufacturing a multi-layer wiring board;

FIG. 7E is an illustrative diagram illustrating the example of the method of manufacturing a multi-layer wiring board;

FIG. 7F is an illustrative diagram illustrating the example of the method of manufacturing a multi-layer wiring board;

FIG. 7G is an illustrative diagram illustrating the example of the method of manufacturing a multi-layer wiring board;

FIG. 7H is an illustrative diagram illustrating the example of the method of manufacturing a multi-layer wiring board;

FIG. 7I is an illustrative diagram illustrating the example of the method of manufacturing a multi-layer wiring board;

FIG. 7J is an illustrative diagram illustrating the example of the method of manufacturing a multi-layer wiring board;

FIG. 7K is an illustrative diagram illustrating the example of the method of manufacturing a multi-layer wiring board;

FIG. 7L is an illustrative diagram illustrating the example of the method of manufacturing a multi-layer wiring board;

FIG. 7M is an illustrative diagram illustrating the example of the method of manufacturing a multi-layer wiring board;

FIG. 7N is an illustrative diagram illustrating the example of the method of manufacturing a multi-layer wiring board;

FIG. 7O is an illustrative diagram illustrating the example of the method of manufacturing a multi-layer wiring board;

FIG. 7P is an illustrative diagram illustrating the example of the method of manufacturing a multi-layer wiring board;

FIG. 7Q is an illustrative diagram illustrating the example of the method of manufacturing a multi-layer wiring board;

FIG. 8A is an illustrative diagram illustrating another example of the method of manufacturing a multi-layer wiring board;

FIG. 8B is an illustrative diagram illustrating the other example of the method of manufacturing a multi-layer wiring board;

FIG. 8C is an illustrative diagram illustrating the other example of the method of manufacturing a multi-layer wiring board;

FIG. 8D is an illustrative diagram illustrating the other example of the method of manufacturing a multi-layer wiring board; and

FIG. 8E is an illustrative diagram illustrating the other example of the method of manufacturing a multi-layer wiring board.

### DETAILED DESCRIPTION OF THE PREFERRED EMBODIMENTS

The present invention will be described in detail below with reference to the accompanying drawings. Modes for carrying out the invention (hereinafter, “embodiment(s)”) do not limit the invention. The elements in the embodiments below include elements that those skilled in the art can imagine easily and elements substantially the same, i.e., equivalents. Furthermore, the elements disclosed in the embodiments can be appropriately combined.

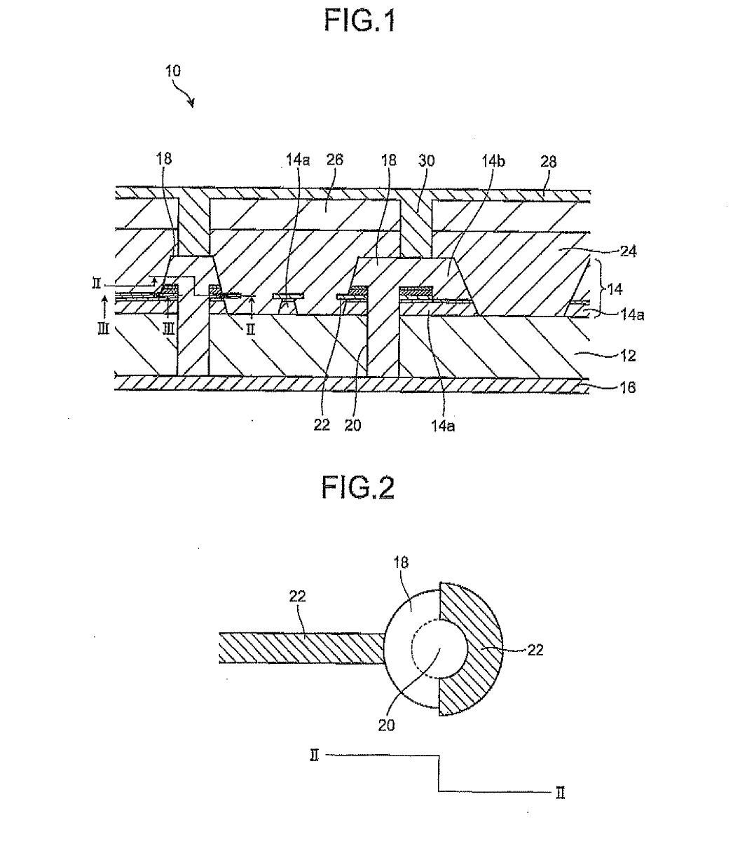

FIG. 1 is a cross-sectional view of a schematic configuration of an embodiment of a multi-layer wiring board. As illustrated in FIG. 1, the multi-layer wiring board (multi-layer wiring circuit board) 10 includes a substrate 12, a first interconnect layer 14, a second interconnect layer 16, a land 18, a via 20, a stress relaxation layer 22, a resin layer 24, a third interconnect layer 26, a metal layer 28, and a via 30.

The substrate 12 is a plate-like member on which interconnect traces serving as a circuit are formed. The substrate 12 is formed of an insulating material, for example, resin. As the resin material that forms the substrate 12, various types of insulating resin materials can be used, for example, vinylbenzyl resin, polyvinyl benzyl ether compound resin, bismaleimide triazine resin (BT resin), polyphenyl ether (polyphenylene ether/oxide) resin (PPE/PPO), cyanate ester resin, epoxy+active ester cured resin, polyphenylene ether resin (polyphenylene oxide resin), curable polyolefin resin, benzo cyclobutene resin, polyimide resin, aromatic polyester resin, aromatic liquid crystal polyester resin, polyphenylene sulfide resin (PPS), polyetherimide resin (PEI), polyacrylate resin, polyether ether ketone resin (PEEK), fluorine resin, epoxy resin, phenol resin, and benzoxazine resin. For the substrate 12, the above-described resins may be independently used. Alternatively, a material may be used that is obtained by adding, to any one of the above-listed resins, silica, talc, calcium carbonate, magnesium carbonate, aluminum hydroxide, magnesium hydroxide, aluminum borate whiskers, potassium titanate fibers, alumina, glass flakes, glass fibers, tantalum nitride, or aluminum nitride. Alternatively, a material may be used that is obtained by adding, to any one of the above-listed resins, metal-oxide powders containing at least one of the metals including magnesium, silicon, titanium, zinc, calcium, strontium, zirconium, tin, neodymium, samarium, aluminum, bismuth, lead, lanthanum, lithium, and tantalum. Alternatively, a material obtained by impregnating, with any one of the above-listed resins, glass fibers, aramid fibers, or nonwoven fabrics can be used. The substrate may be appropriately selected and used in consideration of their electric properties, mechanical properties, water absorbability, and reflow resistance.

The first interconnect layer 14 includes a lower layer interconnect portion 14a and a higher layer interconnect portion 14b. The first interconnect layer 14 is formed on one surface of the substrate 12. The lower layer interconnect portion 14a is formed of a conductive material, such as copper, and is formed on one surface of the substrate 12. The higher layer interconnect portion 14b is an interconnect having a thickness larger than that of the lower layer interconnect portion 14a and is deposited on the interconnect portion of the lower layer interconnect portion 14a as an interconnect portion having a predetermined thickness. The higher layer interconnect portion 14b can be made by, for example, plating. As described above, the first interconnect layer 14 includes a portion, in which only the lower layer interconnect portion 14a is arranged, and a portion, in which the higher, layer interconnect portion 14b is deposited on the lower layer interconnect portion 14a, and thus includes two types of interconnect located at different heights. In the embodiment, a part (the portion indicated by different hatching on the top surface in FIG. 1) of the top surface of the lower layer interconnect portion 14a (the surface on the side opposite to the substrate 12) is roughened.

The second interconnect layer 16 is formed on a surface of the substrate 12 on the side opposite to the surface on which the first interconnect layer 14 is formed. The second interconnect layer 16 is an interconnect pattern having a predetermined thickness and is formed of a conductive member of, for example, copper. As metal used for the first interconnect layer 14 and the second interconnect layer 16, for example, gold (Au), silver (Ag), copper (Cu), nickel (Ni), tin (Sn), chrome (Cr), or aluminum (Al), or tungsten (W) can be used. It is preferable that copper be used for metal films in consideration of its electroconductivity and cost.

Among the first interconnect layer 14, the land 18 is a portion formed corresponding to the via 20 or the via 30 that is described below. The land 18 is formed of a conductive member of, for example, metal (metal the same as that of the lower layer interconnect portion 14a and the higher layer interconnect portion 14b in the embodiment). In other words, among the land 18, an area having a height corresponding to that of the lower layer interconnect portion 14a is formed of the same metal material as that of the lower layer interconnect portion 14a and an area higher than the lower layer interconnect portion 14a is formed of the same material as that of the higher layer interconnect portion 14b. In other words, the land 18 is a metallic portion formed in a portion corresponding to the via 20 or the via 30 and formed to have a thickness approximately equal to that of the portion on which the higher layer interconnect portion 14b is arranged (i.e., the total thickness of the lower layer interconnect portion 14a and the higher layer interconnect portion 14b). The land 18 is formed uniformly with a part of the lower layer interconnect portion 14a or the higher layer interconnect portion 14b. In the land 18, the area of a surface parallel to the surface of the substrate 12 is larger than that of the via 20 and/or via 30 contacting the land 18.

The via 20 is provided to penetrate through the substrate 12. One end portion of the via 20 makes contact with the land 18 and the other end portion makes contact with the second interconnect layer 16. The via 20 allows electrical connection between the land 18 and the second interconnect layer 16, with which the via 20 makes contact, i.e., allows conduction between the land 18 and the second interconnect layer 16. Here, the land 18 is connected to the first interconnect layer 14. Thus, the via 20 allows conduction between a part of the first interconnect layer 14 and a part of the second interconnect layer 16 through the land 18.

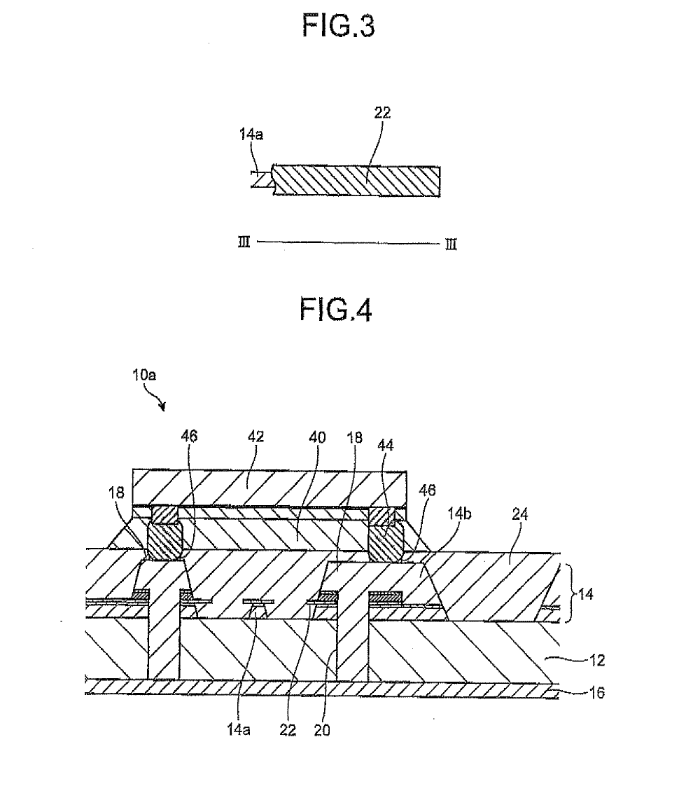

The stress relaxation layer 22 will be described below using FIGS. 1 to 3, FIG. 2 is a cross-sectional view of the multi-layer wiring board in FIG. 1 taken along the line II-II. FIG. 3 is a cross-sectional view of the multi-layer wring substrate in FIG. 1 taken along the line III-III. To clarify the relationship between the stress relaxation layer 22 and the land 18, illustration of a part of the stress relaxation layer 22 is omitted in FIG. 2. Similarly, to clarify the relationship between the stress relaxation layer 22 and the lower layer interconnect portion 14a, illustration of a part of the stress relaxation layer 22 is omitted in FIG. 3. FIGS. 2 and 3 are cross-sectional views taken along a direction in parallel with the substrate as illustrated in FIG. 1.

As illustrated in FIGS. 1, 2, and 3, the stress relaxation layer 22 is arranged in the land 18 and on the surface of the lower layer interconnect portion 14a. As illustrated in FIGS. 1 and 2, the stress relaxation layer 22 is arranged in an area of the land 18, which is the area in which the via 20 is not formed in the direction parallel to the surface of the substrate 12, and on the surface of the lower layer interconnect portion 14a (i.e., the surface on the side opposite to the surface making contact with the substrate 12) in the direction of the thickness of the substrate 12. In other words, the portion of the stress relaxation layer 22, which is a portion provided in the land 18, is arranged between the metal forming the lower layer interconnect portion 14a and the metal of the higher layer interconnect portion 14b. In addition, as illustrated in FIG. 2, in the portion of the stress relaxation layer 22 provided in the land 18, the area of the surface parallel to the surface of the land 18 is larger than the area of the land 18. In other words, the circumferential portion of the stress relaxation layer 22 deviates from the land 18. In addition, as illustrated in FIGS. 1 and 3, the stress relaxation layer 22 is arranged on the surface of the lower layer interconnect portion 14a (i.e., the surface on the side opposite to the surface making contact with the substrate 12). In a portion of the stress relaxation layer 22 provided on the surface of the lower layer interconnect portion 14a, the area of a surface parallel to the surface of the lower layer interconnect portion 14a is larger than the lower layer interconnect portion 14a. For the stress relaxation layer 22, a resin material with high elasticity and high toughness consisting of epoxy resin, a curing agent, and aromatic polyamide resin polymer may be used. It is preferable that a resin material having elongation between 30% and 40% be used for the stress relaxation layer 22. The elongation equal to or more than 30% increases the adhesion of the conductive layer and the elongation equal to or less than 40% appropriately leads to an effect of reducing the stress. The elongation represents elongation (tensile failure elongation) until breaking as a percentage in a tensile strength test (JIS K7113).

The resin layer 24 is arranged on a surface of the resin layer 24 on the side of the first interconnect layer 14. The resin layer 24 covers the entire surface of the first interconnect layer 14 except for the area in which the via 30 to be described below is formed. The resin layer 24 is formed of an insulating material. The third interconnect layer 26 is arranged on a surface of the resin layer 24 on the side opposite to the substrate 12.

The third interconnect layer 26 is provided on a surface of the resin layer 24 on the side opposite to the substrate 12. The third interconnect layer 26 is plate-like in FIG. 1, but is an interconnect pattern. The metal layer 28 is deposited on the top surface of the third interconnect layer 26 (the surface on the side opposite to the surface making contact with the resin layer 24). The metal layer 28 is plating deposited on the third interconnect layer 26 when the via 30 to be described below is formed. This embodiment includes the metal layer 28, but the present invention is not limited to this embodiment. A configuration without the metal layer 28 may be adopted.

The via 30 is provided to penetrate through the resin layer 24. One end portion of the via 30 makes contact with the land 18 and the other end portion makes contact with the third interconnect layer 26. The via 30 allows electrical connection between the land 18 and the third interconnect layer 26, with which the via 30 makes contact, i.e., allows conduction between the land 18 and the third interconnect layer 26. The land 18 is connected to the first interconnect layer 14. Thus, the via 30 allows conduction between a part of the first interconnect layer 14 and a part of the third interconnect layer 26 through the land 18. The via 30 includes the via 30 provided, as illustrated on the center left in FIG. 1, in an area on the line extending in the direction of the thickness of the via in the land 18 (i.e., the area in which a position on the surface parallel to the surface of the substrate 12 overlaps a part of the via 20) and the via 30 provided, as illustrated on approximately the center in FIG. 1, in an area not on the line extending in the direction of the thickness of the via 20 of the land 18 (i.e., the area in which a position on the surface parallel to the surface of the substrate 12 does not overlap the via 20).

In the multi-layer wiring board 10 of the embodiment, by providing the stress relaxation layer 22 as described above, the force from the via 30 to the land 18 can be absorbed in the stress relaxation layer 22. Accordingly, even when stress is concentrated on a part of the land 18, especially on the border surface between the two metal portions (the lower layer interconnect portion 14a and the interconnect portion corresponding to the upper side of the lower layer interconnect portion 14a) constituting the land 18 (i.e., the land 18 and the interconnect layer 14), the stress relaxation layer 22 deforms and thus the influence of the stress can be reduced. This reduces deformation of the land 18 and thus reduces occurrence of failure.

The stress relaxation layer 22 that is deformable is provided on the land 18. Thus, even if the land 18 deforms due to, for example, thermal expansion, the stress relaxation layer 22 deforms in accordance with the deformation, which reduces stress concentration on a part of the land 18.

By providing the stress relaxation layer 22 also on the top surface of the lower layer interconnect portion 14a (the lower layer interconnect portion 14a on which the higher layer interconnect portion 14b is not deposited), the lower layer interconnect portion 14a can be protected. Specifically, when a load is applied to the lower layer interconnect portion 14a via the resin layer 24, the stress relaxation layer 22 deforms and absorbs a predetermined amount of stress. When the lower layer interconnect portion 14a thermally expands and other members thermally expand and deform, the stress relaxation layer 22 deforms and absorbs the displacement (deviation of the relative position between the lower layer interconnect portion 14a and other members) as in the above-described case of the land 18, which further reduces the stress applied to the lower layer interconnect portion 14a.

By forming the stress relaxation layer 22 so as it protrudes from a part of the land 18, i.e., to have a circumference wider than that of the land 18, the stress relaxation layer 22 can be deformable. Accordingly, the stress applied to the land 18 can be appropriately absorbed.

It is preferable that the stress relaxation layer 22 be provided also on the top surface of the lower layer interconnect portion 14a because the above-described effects can be obtained, but the stress relaxation layer 22 may be provided only in an area corresponding to the land 18.

If the stress relaxation layer 22 is provided not on the entire surface of the lower layer interconnect portion 14a, it is preferable that the stress relaxation layer 22 be provided on an area, among the lower layer interconnect portion 14a, that is connected to the land 18 and is on the top surface (the surface covered with the resin layer 24) in a portion within a predetermined distance with respect to the land 18. Accordingly, the stress relaxation layer 22 is arranged in an area on which stress tends to concentrate. Thus, occurrence of failure can be reduced.

The above-described embodiment has the configuration in which an interconnect pattern is further formed on the land and the via is connected to the top surface of the land. However, the object that makes contact with the top surface of the land is not limited to this. In other words, the member that makes contact with the land and is electrically connected to the land is not limited to the via. FIG. 4 is a cross-sectional view of a schematic configuration of another embodiment of the multi-layer wiring board. A multi-layer wiring board 10a in FIG. 4 has a configuration the same as that of the multi-layer wiring board 10 except for a part of the configuration. Detailed description of a configuration of the multi-layer wiring board 10a the same as that of the multi-layer wiring board 10 will be omitted while the same reference numerals are provided thereto, and a configuration unique to the multi-layer wiring board 10a will be focused on and described.

The multi-layer wiring board 10a includes the substrate 12, the first interconnect layer 14, the second interconnect layer 16, the land 1B, the via 20, the stress relaxation layer 22, the resin layer 24, a resin layer 40, an electric part 42, and solder 44. Because the substrate 12, the first interconnect layer 14, the second interconnect layer 16, the land 18, the via 20, the stress relaxation layer 22, and the resin layer 24 are the same as those of the above-described multi-layer wiring board 10, detailed description thereof will be omitted.

The resin layer 40 is provided on a surface of the resin layer 24 on the side opposite to the substrate 12. The resin layer 40 is formed of an insulating material. Furthermore, the electric part 42 is provided on a surface of the resin layer 40 on the side opposite to the substrate 12 (the resin layer 24). The solder 44 is arranged to penetrate through the resin layer 40 and the resin layer 24 between the electric part 42 and the land 18. The solder 44 allows conduction between the electric part 42 and the land 18. The opening in the resin layer 40 and the resin layer 24 in which the solder 44 is arranged serves as a surface opening portion 46. By forming the surface opening portion 46 in the resin layer 40 and the resin layer 24, the surface of the land 18 can be exposed.

In the multi-layer wiring board 10a, the electric part 42 is arranged above the resin later 40. The electric part 42 is connected to the land 18 with the solder 44. Thus, the multi-layer wiring board 10a is arranged on the top surface of the substrate 12 and the land 18 is connected to the external part via the surface opening portion 46. Even if the land 18 is connected to the electric part with the solder 44 as in the multi-layer wiring board 10a, the same effect as that obtained in the above-described case can be obtained by providing the land 18 with the stress relaxation layer 22. The effects obtained by providing the stress relaxation layer 22 on the top surface of the lower layer interconnect portion 14a can be similarly obtained. In other words, when a member that makes contact with the land 18 and applies a force to a part of the land 18 is arranged, the above-described effects can be obtained by a configuration in which the stress relaxation layer is provided.

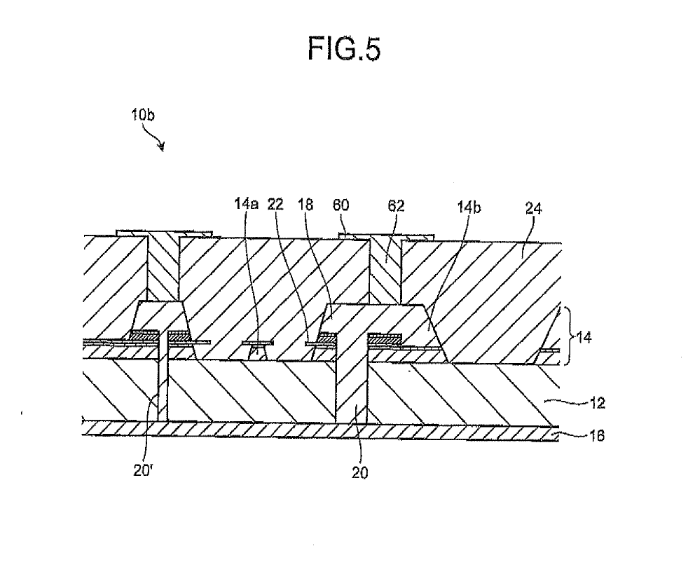

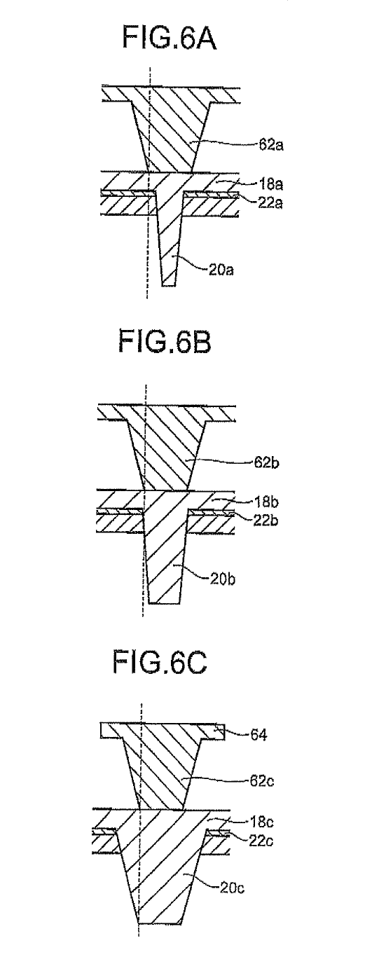

In the above-described embodiment, the relationship between the via arranged under the land and the via arranged on the land is not specifically described, but various configurations can be adopted. These will be described below using FIGS. 5 and 6A to 6C. FIG. 5 is a cross-sectional view of a schematic configuration of another embodiment of the multi-layer wiring board. FIGS. 6A to 6C are schematic diagrams of vias connected to a land, illustrating examples of the relationship thereof. A multi-layer wiring board 10b in FIG. 5 has a configuration the same as that of the multi-layer wiring board 10 excluding a part of the configuration. Detailed description on a configuration of the multi-layer wiring board 10b the same as the configuration of the multi-layer wiring board 10 will be omitted while the same reference numerals are provided thereto, and a configuration unique to the multi-layer wiring board 10b will be focused on and described.

The multi-layer wiring board 10b includes the substrate 12, the first interconnect layer 14, the second interconnect layer 16, the land 18, the via 20, a via 20′, the stress relaxation layer 22, the resin layer 24, a third interconnect layer 60, and a via 62. Because the substrate 12, the first interconnect layer 14, the second interconnect layer 16, the land 18, the via 20, the stress relaxation layer 22, and the resin layer 24 are the same as those of the above-described multi-layer wiring board 10, detailed description thereof will be omitted.

The third interconnect layer 60 is provided on a surface of the resin layer 24 on the side opposite to the substrate 12. The basic configuration of the third interconnect layer 60 is the same as that of the third interconnect layer 26 except that the wiring pattern is different. The via 62 is provided to penetrate through the resin layer 24. One end portion of the via 62 makes contact with the land 18 and the other end portion makes contact with the third interconnect layer 60. The via 62 allows electrical connection between the land 18 and the third interconnect layer 60 with which the via 62 makes contact.

In the multi-layer wiring board 10b, the diameter of the via 20′ is smaller than that of the via 20. The diameter of the via is the diameter of the cross section of the via (the plane parallel to the surface of the substrate). In the multi-layer wiring board 10b, the via diameter varies depending on the position in which a via is formed.

Even when the shape of the via varies depending on its position in the multi-layer wiring board 10b, effects the same as those of the multi-layer wiring board 10 can be obtained by providing the stress relaxation layer 22.

The via 62 and the via 20 are similar in the relationships in FIGS. 6A to 6C. A via 62a in FIG. 6A has a shape in which the diameter decreases toward a via 20a (i.e., a land 18a). The via 20a has a shape in which the diameter decreases as it separates from the via 62a (i.e., the land 18a). The via 62a has a shape in which the diameter at a portion making contact with the land 18a (the via bottom) is larger than that of the end portion of the via 20a on the side of the land 18a (the via top).

Even with the relationship between the via 62a and the via 20a, the concentration of stress applied from the via 62a on the land 18a is reduced by providing a stress relaxation layer 22a. In this case, because the diameter of the via 20a is small, the load applied to the connection point between the via 20a and the land 18a particularly increases. For this reason, effects obtained by providing the stress relaxation layer 22a are remarkable.

A via 62b in FIG. 6B similarly has a shape in which the diameter decreases toward the via 20, and a via 20b has a shape in which the diameter decreases as it separates from the via 62b. The via 62b has a shape in which the diameter at a portion making contact with a land 18b (the via top) is the same as the diameter of the end portion of the via 20b on the side of the land 16b (the via top). Even with the relationship between the via 62b and the via 20b, the concentration of stress applied from the via 62b on the land 18b can be reduced by providing a stress relaxation layer 22b.

A via 62c in FIG. 6C similarly has a shape in which the diameter decreases toward a via 20c, and the via 20c has a shape in which the diameter decreases as it separates from the via 62c. The via 62c has a shape in which the diameter at a portion making contact with a land 18c (the via top) is smaller than the diameter of the end portion of the via 20c on the side of the land 18c (the via top). Even with the relationship between the via 62c and the via 20c, the concentration of stress applied from the via 62c on the land 18c can be reduced by providing a stress relaxation layer 22c.

In the examples in FIGS. 6A to 6C, the via 62 and the via 20 are compared with each other. If the relationship between the via 62 (the via arranged on the land 18) and the inner diameter of the stress relaxation layer 22 satisfies the above-described relationship, the same effects can be obtained. In other words, if the diameter of the via top of the via 20 instead of the inner diameter of the stress relaxation layer 22 satisfies the above-described relationship, effects the same as those described above can be obtained. Furthermore, when the relationships each between the via 62 and the via 20 in FIGS. 6A to 6C are compared, if the relationship in FIG. 6A is satisfied, i.e., if the via 62 has a shape in which the diameter at the portion making contact with the land 18 (the via bottom) is larger than the end portion of the via 20 on the side of the land 18 (the via top), more remarkable stress relaxation effects can be obtained.

It is preferable that the stress relaxation layer 22 have a thickness of 0.5 μm to 5 μm. A thickness equal to or more than 0.5 μm reduces the difference in the linear expansion between the resin layer and the metal via. A thickness equal to or less than 5 μm reduces the load in a step of forming a resin layer.

It is preferable that the stress relaxation layer be arranged on the side of the circumference of the land. It is also preferable that the stress relaxation layer be arranged surrounding the circumference of the via on the plane surface parallel to the surface of the substrate. This maintains the low electric resistance in the land and increases the durability of the land.

It is preferable that, on the surface on which a portion corresponding to the lower layer interconnect portion (a first conducting member) and an interconnect portion (a second conducting member) above the portion, constituting the land, overlap with each other, an inner end portion of the stress relaxation layer be arranged on a part within a distance of 2% to 90% from the outer edge to the center. If the position of the inner end portion of the stress relaxation layer corresponds to 2% of the distance from the outer edge to the center or more, the diameter of the center opening of the stress relaxation layer can be larger than the diameter of the bottom layer of the land. If the position corresponds to 9.0% of the distance or less, a predetermined connection resistance of the land or less can be maintained.

It is unnecessary to provide the stress relaxation layer all around the outer circumference of the land, but it is preferable that the stress relaxation layer be provided on 30% of the outer circumference of the land or more. With the stress relaxation layer on 30% of the outer circumference of the land or more the above-described effects can be preferably obtained. It is preferable that the stress relaxation layer be provided around a portion in which the land and the lower interconnect layer are connected. This appropriately reduces the stress concentration.

It is also preferable that the relationship between the diameter of the land and the diameter of the via be in a predetermined range. For example, when the diameter of the land is 0.5 mm, it is preferable that the diameter of the via be in the range of 0.05 mm to 0.08 mm. In other words, it is preferable that the diameter of the land be 6.26 to 10 times the diameter of the via. This maintains high durability of the land and the via and maintains the electric resistance at a predetermined level or less.

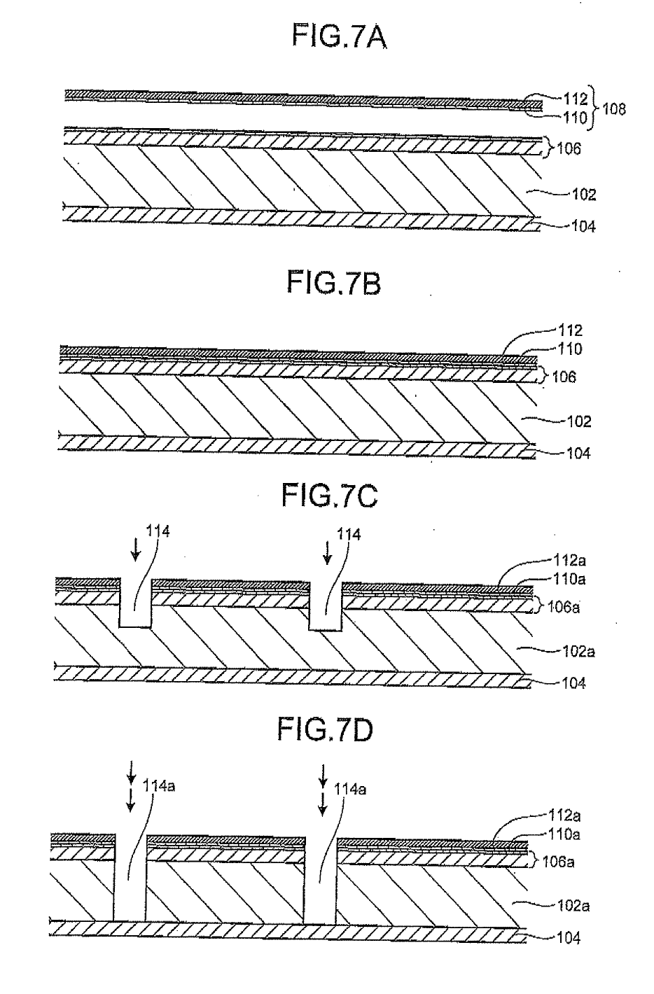

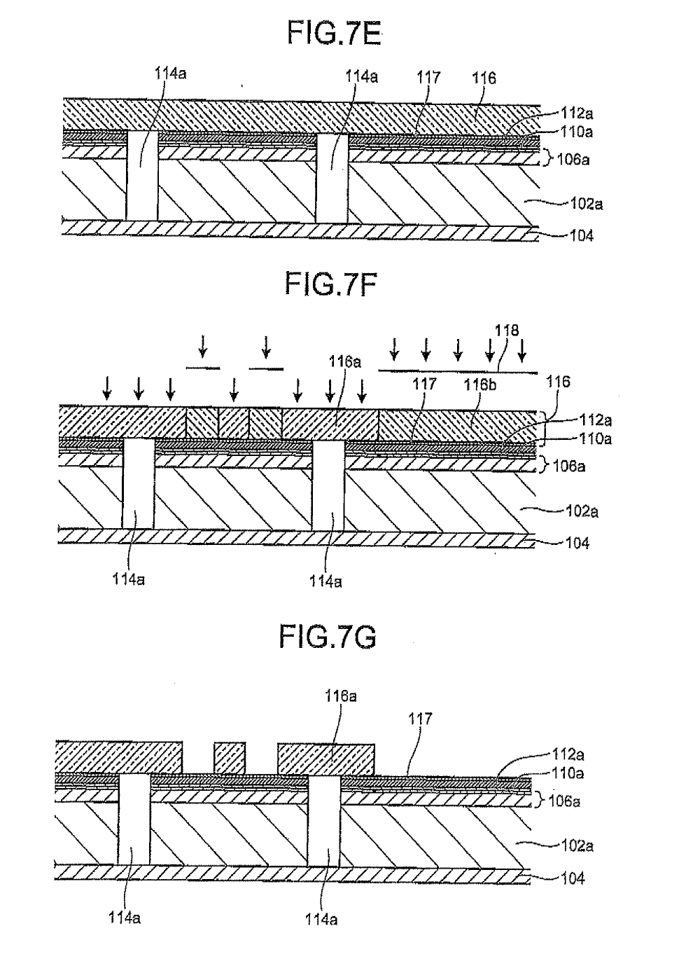

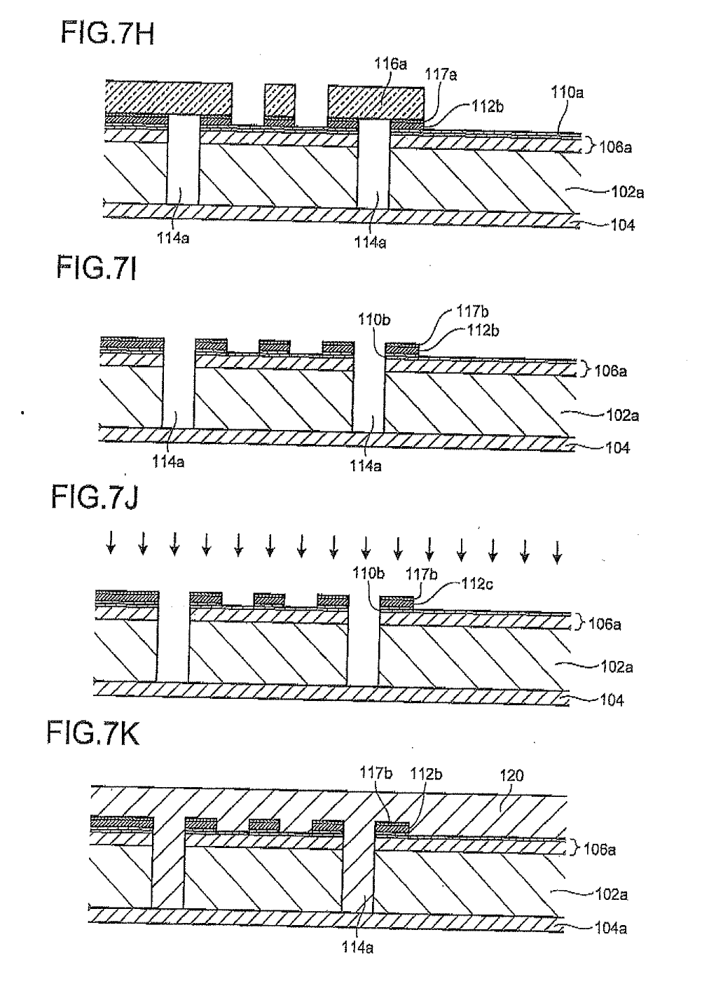

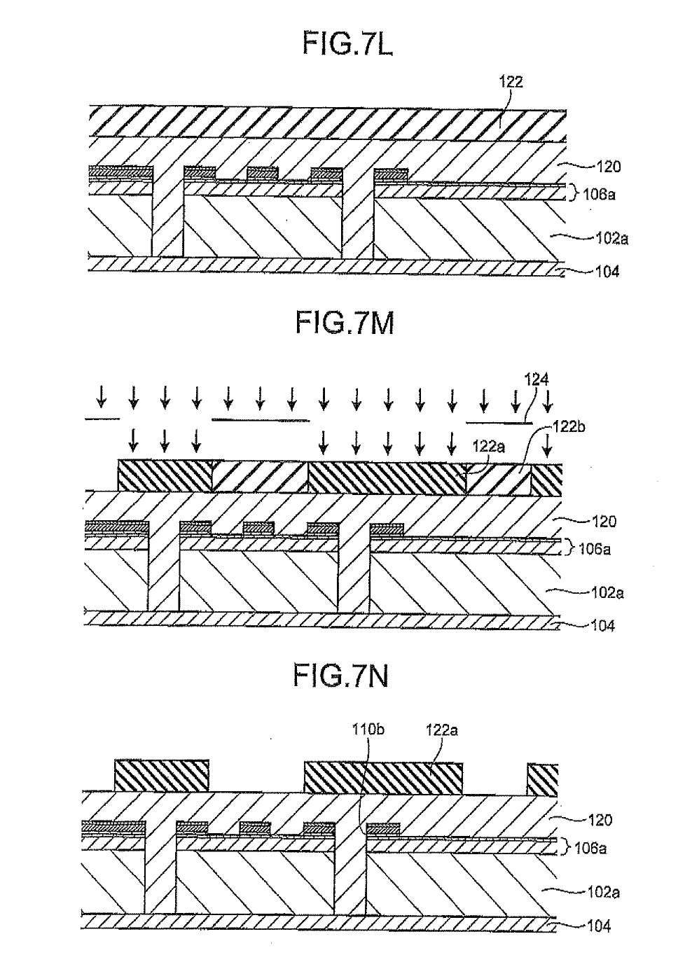

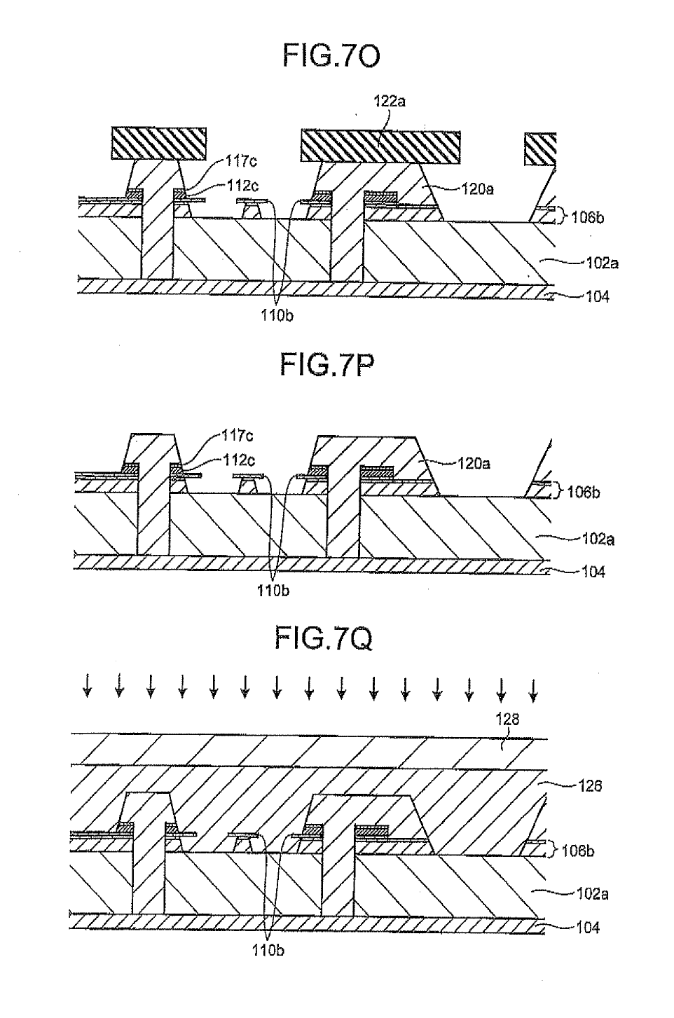

A method of manufacturing a multi-layer wiring board will be described using FIGS. 7A to 7Q. FIGS. 7A to 7Q are illustrative diagrams illustrating an example of manufacturing a multi-layer wiring board. A multi-layer wiring board can be manufactured by a manufacturing apparatus including a manipulator and having various functions, such as a semiconductor processing function. The manufacturing apparatus may be separated into multiple devices. An operator may perform transfers between devices and arrangement of parts.

First, as illustrated in FIG. 7A, a substrate 102, with a metal film (metal foil) 104 arranged on one surface and a metal film (metal foil) 106 arranged on the other surface, and a primer metal foil 108 are prepared. As the substrate 102 on which the metal films 104 and 106 are arranged, double-sided CCL (copper clad laminate) can be used. For the metal films, as in the case of the above-described interconnects, for example, gold (Au), silver (Ag), copper (Cu), nickel (Ni), tin (Sn), chrome (Cr), aluminum (Al), or tungsten (W) may be used. In the substrate 102, the metal film 106 is roughened (the roughened portion of the metal film 106 is represented by hatching different from those of other portions in FIG. 7A). A roughening process or flat bonding (corrosion inhibition process using resin with imidazole) can be performed. The roughening process does not have to be performed. The primer metal foil 108 is an integrated plate-like member including a primer 110 and a metal foil 112b and in which the primer 110 is adhered to one surface of a metal foil 112. As the primer metal foil 108, the plate-like member whose one surface has a CCL structure can be used. For the primer 110, resin consisting of resin (for example, epoxy resin), a curing agent, and aromatic polyamide resin polymer may be used. The thickness of the primer 110 is not specifically limited. For example, the thickness of the primer 110 may be between 0.1 μm and 5 μm. The thickness of the metal foil 112 may be between 0.1 μm and 12 μm.

The manufacturing apparatus arranges the primer 110 of the primer metal foil 108 on a surface of the substrate 102 on the side of the metal film 106 in FIG. 7A. The primer 110 is then cured so that, as illustrated in FIG. 7B, the primer 110 and the metal film 106 are joined to each other. Accordingly, the primer 110 and the metal foil 112 are layered on the metal film 106 on the substrate 102.

The manufacturing apparatus then irradiates a predetermined position on the laminated body from the side of the metal foil 112 with a UV-YAG laser or a direct CO₂ laser, thereby forming holes 114 in the laminated body as illustrated in FIG. 7C. Each hole 114 penetrates through a metal foil 112a, a primer 110a, and a metal film 106a and extends to a part of a substrate 102a. The manufacturing apparatus then further deepens the formed holes using, for example, a CO₂ laser so that, as illustrated in FIG. 7D, holes 114a reach the metal film 104. It is satisfactory if the holes 114a reach the metal film 104. The holes 114a do not penetrate through the metal film 104. The hole 114a is a hole in which a via is formed. The hole is formed by two steps in the embodiment, but the present invention is not limited to this. The hole may be formed in one step. It is preferable that the manufacturing apparatus has a step of performing a roughening process by etching the surface of the hole 114a. By roughening the hole 114a, the adherence to the metal increases when a via is formed.

As illustrated in FIG. 7E, the manufacturing apparatus then layers a dry film, in which a metal foil 117 is arranged on the entire surface of a resist 116, on the metal foil 112a of the laminated body in which the hole 114a is formed. The manufacturing apparatus joins the metal foil 117 and the metal foil 112a. In other words, the dry film is adhered to the laminated body such that the resist 116 is arranged in a position the most distant from the substrate 102a. A portion of the metal foil 117 opposed to the hole 114a serves as an opening.

After adhering the dry film to the laminated body, as illustrated in FIG. 7F, the manufacturing apparatus arranges a mask 118 on a surface opposed to the resist 116 and exposes the resist 116. Accordingly, a part of the resist 116 serves as an exposed resist 116a and the rest serves as an unexposed resist 116b. An opening is formed in the mask 118 such that an area on which the primer 110 is left on the metal film 106 serves as an exposed area. In the resist 116, the exposed portion remains in development and the unexposed portion is removed by development.

After exposing the resist 116, the manufacturing apparatus removes the mask 118 and then develops the laminated body. Accordingly, as illustrated in FIG. 7G, only the exposed resist 116a remains in the laminated body and only the unexposed resist 116b is removed. Thereafter, the manufacturing apparatus removes the metal foil 117 and the metal foil 112a, on which the exposed resist 116a is not arranged, by etching using the exposed resist 116a as a mask. Thus, in the laminated body, as illustrated in FIG. 7H, a metal foil 117a and the metal foil 112a are partly removed according to the pattern of the exposed resist 116a and thus a part of the primer 110a is exposed.

Thereafter, as illustrated in FIG. 7I, the manufacturing apparatus then removes the exposed resist 116a from the laminated body. The manufacturing apparatus then removes a part of the primer 110a, specifically, a portion not covered with the metal foil 112b, using a metal foil 117b and the metal foil 112b as a mask. Accordingly, a primer 110b is obtained as illustrated in FIG. 7J. The primer is removed by etching a part of the primer by applying media, such as a laser beam, wet blast media, or desmear media.

The manufacturing apparatus then forms a metal film on the surface of the laminated body by electrolytic plating and then grows the metal film by electrolytic plating. Accordingly, as illustrated in FIG. 7K, a plated portion 120 is formed on the laminated body. The plated portion 120 is formed to fill the hole 114a and cover the entire surface of the substrate 102a on the side of the metal film 106a. The plated portion 120 may be formed by non-electrolytic plating.

The manufacturing apparatus then, as illustrated in FIG. 7L, provides a resist 122 on the surface of the plated portion 120. The manufacturing apparatus then, as illustrated in FIG. 7M, arranges a mask 124 on a surface opposed to the surface of the resist 122 and exposes the resist 122. Accordingly, a part of the resist 122 serves as an exposed resist 122a and the rest serves as an unexposed resist 122b. An opening is formed in the mask 124 such that the resist in an area corresponding to the plated portion 120 to be left in the laminated body is exposed. When the resist 122 is exposed, it gets properties that it does not dissolve in development.

The manufacturing apparatus then develops the laminated body so that, as illustrated in FIG. 7N, the exposed resist 122a is left on the surface of the plated portion 120 and the unexposed resist 122b is removed from the laminated body. The manufacturing apparatus then performs an etching process using the resist 122a as a mask. As the etching process, wet etching can be used. Accordingly, in the laminated body, as illustrated in FIG. 7O, the portion of the plated portion on which the exposed resist 122a is not arranged is removed. In addition, among the metal film 106a, an area on which the exposed resist 122a is not arranged and the primer 110b is not arranged is removed. Accordingly, in the laminated body, a metal film 106b, the primer 110b, a metal foil 112c, a metal foil 117c, a plated portion 120a, and the exposed resist 122a are layered on the substrate 102a. The metal film 104 is arranged on the surface of the substrate 102a on the side opposite to the surface on which the metal film 106b is arranged.

The manufacturing apparatus then, as illustrated in FIG. 7P, removes the exposed resist 122a from the laminated body. Thereafter, after building up a resin layer and flattening the surface of the laminated body, the manufacturing apparatus deposits a metal layer so that, as illustrated in FIG. 7Q, a resin layer 126 and a metal layer 128 are layered.

Thereafter, the manufacturing apparatus forms holes (vias) and forms plating and an interconnect pattern, thereby forming the above-described multi-layer wiring board 10.

With the above-described manufacturing method, an interconnect pattern in which the thickness of the board differs depending on the position can be manufactured. In other words, the portion in which only the metal film 106b remains serves as the lower layer interconnect portion and the portion in which the metal film 106b and the plated portion 120a remain serves as the higher layer interconnect portion or a land. Specifically, a portion formed around the via serves as the land. Thus, interconnect portions at different heights can be manufactured efficiently. Specifically, manufacturing can be done by performing wet etching only once.

According to the above-described manufacturing method, the primer 110b can be left around the land and the primer 110b can be used as a stress relaxation layer. Thus, a multi-layer wiring board that achieves the above-described effects can be manufactured efficiently. By using the above-described manufacturing method, a stress relaxation layer wider than a lower interconnect layer on the plane parallel to the substrate can be formed on the lower interconnect layer, and a stress relaxation layer partly exposed from the land can be formed. The relationship between the sizes of the lower interconnect layer and the stress relaxation layer can be varied by adjusting etching conditions and adjusting the shape of the mask.

The primer on the lower interconnect layer is left in the above-described embodiment, but the primer can be removed after the step in FIG. 7P.

The order in which holes serving as vias are formed is not limited to the above-described order. For example, holes can be formed after the step in FIG. 7H, the step in FIG. 7I, or the step in FIG. 7J.

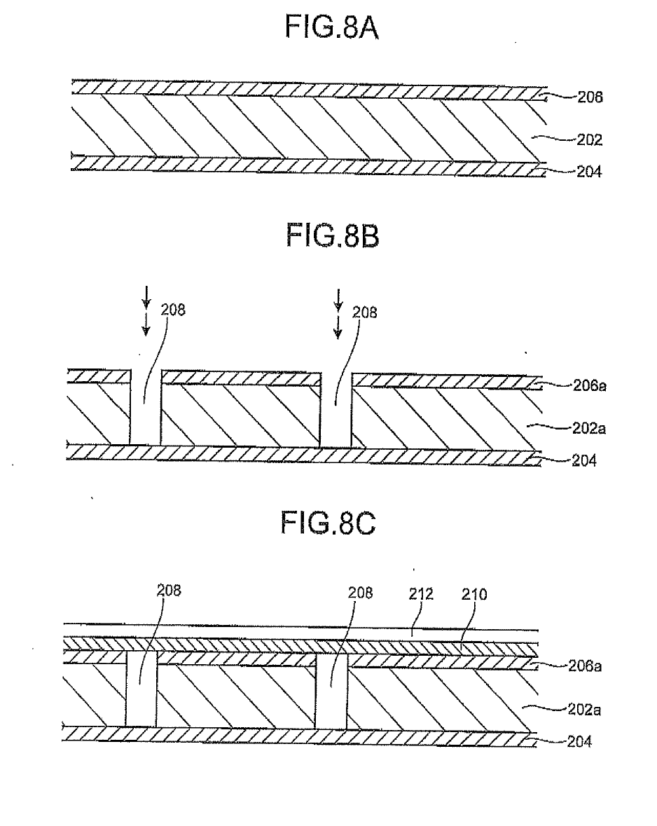

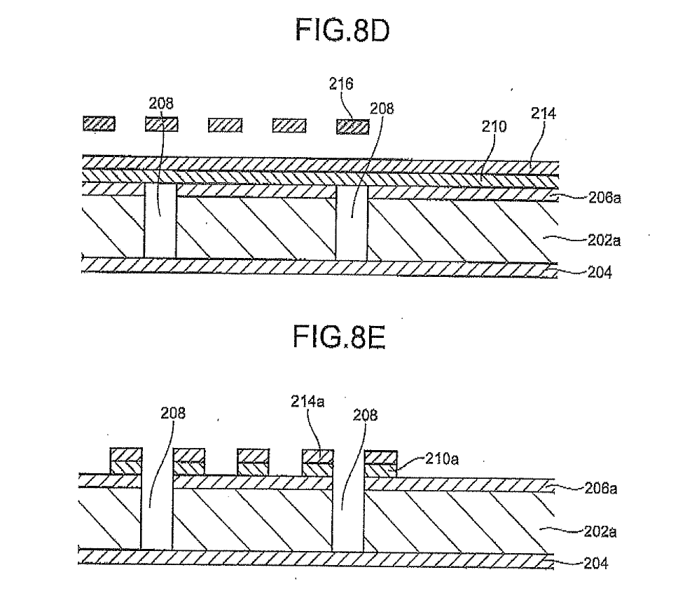

In the above-described embodiment, the stress relaxation layer is formed by leaving the primer. However, the method of manufacturing a multi-layer wiring board including a stress relaxation layer is not limited to this. Other examples of the method of manufacturing a multi-layer wiring board will be described using FIGS. 8A to 8E. FIGS. 8A to 8E are each an illustrative diagram illustrating another example of the method of manufacturing a multi-layer wiring board.

In the embodiment, as described above and as illustrated in FIG. 8A, a substrate 202 with a metal film (metal foil) 204 arranged on one surface and a metal film (metal foil) 206 arranged on the other surface is prepared.

As illustrated in FIG. 8B, the manufacturing apparatus irradiates a predetermined position on the laminated body from the side of the metal film 206 with a UV-YAG laser, direct CO₂ laser, or CO₂ laser, thereby forming holes 208 penetrating through a substrate 202a and a metal film 206a and reaching the metal film 204. It is satisfactory if the holes 208 reach the metal film 204. The holes 208 do not penetrate through the metal film 204. The hole 208 serves as a hole in which a via is formed.

The manufacturing apparatus then, as illustrated in FIG. 8C, arranges a primer 210 on a surface of the laminated body on the side of the metal film 206a. As illustrated in FIG. 8C, the primer 210 is adhered (bonded or joined) to the metal film 206a using a metal layer 212 that supports the primer 210. After the primer 210 is attached to the metal film 206a, the metal layer 212 is removed (detached) from the laminated body. Thus, only the primer 210 is left on the surface of the metal film 206a.

Thereafter, the manufacturing apparatus arranges a resist 214 on the top surface of the primer 210 as illustrated in FIG. 8D. The manufacturing apparatus then arranges a mask 216 on a surface opposed to the resist 214 and exposes the mask 216. Accordingly, among the resist 214, an area corresponding to the opening of the mask 216 is exposed. In the embodiment, only an area in which the stress relaxation layer is arranged and an area in which a lower layer interconnect portion is formed are exposed.

The manufacturing apparatus then performs a development process on the laminated body so that, as illustrated in FIG. 8E, only a part of the resist 214 and the primer 210 (a resist 214a and a primer 210a) is left on the metal film 206a. In other words, by performing the development process on the laminated body, the resist 214 and the primer 210 are partly removed. A portion of the resist 214 and a portion of the primer 210 corresponding to each other are removed. In other words, the primer 210 is etched using, as a mask, a resist 214a that is an exposed portion in the resist 214. After forming the primer 210a as illustrated in FIG. 8E, the manufacturing apparatus removes the resist 214a from the laminated body. Thereafter, the manufacturing apparatus performs the process in FIG. 7K and the following process, thereby providing a stress relaxation layer like that obtained by the above-described manufacturing method.

In the method in FIGS. 8A to 8E, the surface portion of the substrate 202a exposed to the hole 208 is roughened by etching during development and non-electrolytic plating may be performed between steps in FIGS. 8B and 8C.

The manufacturing method is not limited to the above-described one. The primer metal foil 108 may be layered after holes are formed, and a stress relaxation layer may be formed by removing a part of the primer using the same above-described method.

In a multi-layer wiring board and a method of manufacturing a multi-layer wiring board according to the present invention, effects are realize in which, even if a large load is applied, force concentration on an interconnect layer is reduced, thereby reducing occurrence of failures and increasing multi-layer wiring board's reliability as a circuit board.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A multi-layer wiring board comprising:
a substrate;
a land that includes a first conductive member arranged on the substrate, a second conductive member deposited on a surface of the first conductive member, and a stress relaxation layer arranged between the first conductive member and the second conductive member, the surface of the first conductive member being distant from the substrate; and
a connection portion that makes contact with the land and that is electrically connected to the land.

2. The multi-layer wiring board according to claim 1, wherein the stress relaxation layer contains resin.

3. The multi-layer wiring board according to claim 1, wherein the stress relaxation layer is arranged on the side of the circumference of a surface on which the first conductive member and the second conductive member overlap with each other.

4. The multi-layer wiring board according to claim 3, wherein the stress relaxation layer has an inner end portion arranged on the surface, on which the first conductive member and the second conductive member overlap with each other, in a part within a distance of 2% to 90% from the outer edge to the center.

5. The multi-layer wiring board according to claim 1, wherein the stress relaxation layer has, on a plane parallel to the substrate, at least a portion that protrudes from the surface on which the first conductive member and the second conductive member overlap with each other.

6. The multi-layer wiring board according to claim 1, further comprising a first conductive member that is arranged on the substrate and on which the second conductive member is not deposited,
wherein the stress relaxation layer is also arranged on the first conductive member on which the second conductive member is not deposited.

7. A method of manufacturing a multi-layer wiring board comprising:
adhering a resin layer to a plate-like substrate with a first metal layer arranged on one surface and a second metal layer arranged on the other surface on the surface on which the first metal layer is arranged;
forming a hole that penetrates through the first metal layer and the substrate and extends to the second metal layer;
patterning the resin layer, leaving at least the resin layer around the hole; and
filling the hole, the first metal layer, and the resin layer with metal.

8. The method of manufacturing a multi-layer wiring board according to claim 7, further comprising:
forming a patterned filled-metal resin layer on the filled metal after filling the metal; and
removing the filled metal and the first metal layer using the resin layer and the filled-metal resin layer as a mask.
